(19) United States
(12) Patent Application Publication
(10) Pub. No.: US 2004/0207476 A1
(43) Pub. Date: Oct. 21, 2004

(54) PLL circuit and television receiver having same and beat reducing method for television receiver

(76) Inventor: Tsuyoshi Itaya, Osaka (JP)

Correspondence Address: BIRCH STEWART KOLASCH & BIRCH, PO BOX 747, FALLS CHURCH, VA, 22040-0747, US

(21) Appl. No.: 10/781,672

(22) Filed: Feb. 20, 2004

(30) Foreign Application Priority Data
Apr. 21, 2003 (JP) 2003-115849

(51) Int. Cl. H03K 3/26

(52) U.S. Cl. 331/177 V

(57) ABSTRACT

A PLL circuit is used for a super-heterodyne television receiver. In the PLL circuit, a reference signal oscillator circuit generates a reference signal, and the reference signal is compared to a LO signal in a phase comparator. The phase comparator includes (i) an oscillating circuit, (ii) a series circuit of a correcting capacitor and an oscillator corresponding to a predetermined IF signal frequency, (iii) another correcting capacitor, and (iv) a switch. The switch is turned ON or OFF only when receiving a particular channel in which interference occurs, so as to shift the frequency of the reference signal by several ten kHz. This reduces beats in a particular channel, and prevents deterioration of picture quality in other channels. That is, interference in a particular channel can be reduced without causing any adverse effects in other channels having a relatively high frequency.

This Nonprovisional application claims priority under 35 U.S.C. § 119(a) on Patent Application No. 2003/115849 filed in Japan on Apr. 21, 2003, the entire contents of which are hereby incorporated by reference.

### FIELD OF THE INVENTION

The present invention relates to (i) a PLL circuit suitable for a receiver adopting a super-heterodyne system, such as a television receiver, (ii) a television receiver having the PLL circuit, and (iii) a beat reducing method for the television receiver.

### BACKGROUND OF THE INVENTION

FIG.5 is a block diagram which illustrates a circuitry of an ordinary television receiver 1 compatible with the NTSC and PAL broadcast system adopting the super-heterodyne system. A received RF (radio frequency) signal supplied via an antenna 2 is filtered by an input tuning circuit 3 including a band pass filter such that only desired signal is extracted, and then the signal thus extracted is amplified by a radio frequency amplifying circuit 4. The signal thus amplified is supplied to an interstage tuning circuit 5, including a band pass filter, which removes unnecessary signal components. The RF signal is supplied to a mixing circuit 6, and is mixed with an LO (local oscillation) signal generated by a local oscillating circuit 7 such that the frequency of the RF signal is converted to an IF (intermediate frequency) signal.

The IF signal is supplied to a SAW filter 8 which is compatible with the NTSC and PAL broadcasting system such that a video signal component (VIF signal) and a sound signal component (SIF signal) are picked up. Separate SAW filters may be used for the video signal component and the sound signal component, respectively. The VIF signal is supplied to an amplifying circuit (VIF AMP) 9. The SIF signals are supplied to a sound IF amplifying circuit (SIF AMP) 10.

The VIF signal amplified by the amplifying circuit 9 is subjected. to video detection in a video detecting circuit (Video DET) 11, so as to be outputted as a video signal, and then the video signal is amplified by a video amplifying circuit (Video AMP) 12, and is outputted. On the other hand, the SIF signal is detected (frequency-converted) by a sound demodulation circuit (QIF DET) 13, and become a 4.5 MHz SIF signal for the NTSC standard or 5.5 MHz SIF signal for the PAL B/G standard. The SIF signal is subjected to FM wave detection in an FM wave detecting circuit (FM DET) 14, and is then outputted as a sound signal.

As described above, the frequency of the receiving RF signal is first converted into an IF signal. Then, the IF signal is divided into a video signal component (VIF signal) and a sound signal component (SIF signal). Finally, the SIF signal is mixed with an LO (local oscillation) signal, and is then demodulated, so as to be outputted as a sound signal. The reason for this is that the lower the frequency is, the simpler the circuitry of a detector is and the better the performance of the detector. Therefore, most detectors firstly convert the frequency of a sound carrier signal to the frequency of a SIF signal before carrying out demodulation.

FIG.6 is a block diagram which illustrates a circuitry of a typical conventional PLL circuit 21. The PLL circuit 21 includes an oscillator 22 which oscillates the LO signal, a reference signal oscillator 23, a phase comparator 24, and frequency dividers 25, 26. The oscillator 22 is realized by a voltage control oscillator which oscillates the LO signal at a frequency corresponding to the DC control voltage fed by the phase comparator 24. The reference signal oscillator 23 includes (i) a series circuit of a correcting capacitor 28 and an oscillator 27 made of a substance like crystal or ceramic, and (ii) an oscillating circuit 29. The oscillating circuit 29 oscillates at a predetermined constant frequency set by the series circuit. In the series circuit, either of the oscillator 27 and the correcting capacity 28 may be on the GND side. An LO signal component generated in the oscillator 22 is divided in the frequency divider 25 and a reference signal component generated in the normal signal oscillator 23 is divided in the frequency divider 26. Then, these divided components are compared with each other in the phase comparator 24, and are subjected to feedback control in which the DC control voltage is varied to set the same phase for the divided components. The dividing ratio of the frequency divider 25 and/or the frequency divider 26 is varied to convert a given RF frequency to a predetermined IF frequency in the mixing circuit 6 of a television receiver in FIG.5, enabling the user to see a channel corresponding to the RF frequency.

Based on the PLL circuit 21 of the foregoing structure, description is made below as to the mechanism by which interference is generated, using an example of a television receiver which uses 45.75 MHz for the video IF frequency. (Here, the exemplary television receiver generally conforms to the standard, 45.75 MHz, adopted in the United States, but it has also been adopted recently in Japan in order to achieve compatibility between the United States and Japan.)

When the television receiver whose video IF frequency is set at 45.75 MHz receives a channel whose video RF frequency is 91.25 MHz (USA: channel A-5, JPN: channel 1), the LO signal frequency used to receive the channel is represented by the following equation: 91.25+45.75=137 MHz. Therefore, when the RF signal is mixed with the LO signal, the video IF signal of 45.75 MHz is picked up.

However, in this case, a 46 MHz interference component, which is produced by mixing a double harmonic wave of the RF signal and the LO signal, is outputted from the mixing circuit 6 (91.25×2−137=46 MHz). The interfering component is mixed with the video IF component in a subsequent stage circuit, and an interference component of 250 kHz is outputted together with the video signal (46−45.75=0.25 MHz=250 kHz). The interference component appears as striped pattern beats. The 250 kHz beat component is easily recognizable with human eyes. It is also very difficult to reduce beats.

Incidentally, it is well known that the beat component becomes hardly unrecognizable with human eyes when the beat component of 250 kHz is shifted by several ten kHz. Therefore, in the typical conventional PLL circuit 21, an LO signal frequency is shifted by several ten kHz in order to prevent interference. Specifically, the frequency of the LO signal is shifted by several ten kHz by slightly shifting the oscillating frequency of the reference signal. The oscillating frequency of the reference signal is determined by the oscillator 27 and the correcting capacitor 28 of an oscillating frequency.

One prior art example relating to the present invention is Japanese Publication for Unexamined Patent Application No. 2001/339652 (Tokukai 2001-339652, published on Dec. 7, 2001). For convenience of explanation, details of this conventional art will be described in the DESCRPTION OF THE EMBODIMENT section.

In the PLL circuit 21 of the conventional example, interference can be reduced in a particular channel with a video RF frequency of 91.2 MHz, as in channel A-5 in the U.S and channel 1 in Japan. However, the LO signal frequency shifts from the reference frequency on the order of several hundred kHz in a channel having a high LO signal frequency, including UHF channel in particular. As a result, the IF signal component produced by the frequency-conversion with the LO signal is also shifted on the order of several hundred kHz. When the IF signal with a frequency shift. is detected, the resulting video frequency characteristics cannot be obtained as originally intended. This causes the problem of picture deterioration. That is, the conventional art shifts the LO signal frequency in favor of a picture quality in a particular channel over the adverse effect of image deterioration in a channel with a high LO signal frequency.

An object of the present invention is to provide (i) a PLL circuit which reduces interference without causing any adverse effect on other channels having a relatively high frequency, and (ii) a television receiver having such a PLL circuit and (iii) a beat reducing method for a television receiver.

### SUMMARY OF THE INVENTION

A PLL circuit of the present invention is used for a super-heterodyne receiver, and includes (i) a shifting circuit for shifting a predetermined frequency of a reference signal, and (ii) a control circuit for causing the shifting circuit to shift the predetermined frequency of the reference signal in a channel in which interference occurs.

A PLL circuit of the present invention is used for a super-heterodyne receiver, and outputs a local oscillating signal. The PLL circuit includes a reference signal oscillating circuit for oscillating a reference signal used to determine a frequency of the local oscillating signal. The reference signal oscillating circuit includes (i) an oscillating circuit, (ii) a shifting circuit for shifting a predetermined frequency of the reference signal oscillated by the oscillating circuit, and (iii) a control circuit for causing the shifting circuit to shift the predetermined frequency of the reference signal in a channel in which interference occurs.

The PLL circuit of the present invention according to the foregoing structure is used, for example, in a super-heterodyne receiver in which a radio frequency (RF) signal of a selected channel is picked up as an intermediate frequency (IF) signal after it is mixed with a local oscillator (LO) signal whose frequency is controlled by the PLL circuit, and in which a base band signal is demodulated from the IF signal.

In a conventional PLL circuit, an interfering component is added to a predetermined IF frequency when a double harmonic wave of a relatively low RF frequency in a particular channel is mixed with an LO frequency, with the result that a beat is generated. On the other hand, in the structure of the present invention, the control circuit causes the shifting circuit to shift the frequency of the reference signal in the PLL circuit only for a channel in which interference occurs. This brings about a shift in the LO signal frequency, causing the interfering component to shift to a frequency which is almost unrecognizable. As a result, interference in the particular channel is reduced.

By thus shifting the frequency of the reference signal not for the entire channels but only for the particular channel, the frequency of the LO signal will not greatly shift from its specific value in a channel having a relatively high frequency. There accordingly will be no great shift of the IF signal frequency from its specific value, thus preventing deterioration of signal quality in the base band signal.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a block diagram illustrating a circuitry of the PLL circuit in one embodiment of the present invention.

FIG.2 is a block diagram explaining a concrete structure of a reference signal oscillating circuit in the PLL circuit shown in FIG. 1.

FIG.3 is a block diagram explaining a concrete structure of a reference signal oscillating circuit in the PLL circuit shown in FIG. 1.

FIG.4 is a block diagram illustrating a circuitry of the PLL circuit in another embodiment of the present invention.

FIG.5 is a block diagram illustrating a circuitry of a common conventional television receiver adopting a super-heterodyne system.

FIG.6 is a block diagram illustrating a circuitry of a typical conventional PLL circuit.

### DESCRIPTION OF THE EMBODIMENTS

[First Embodiment]

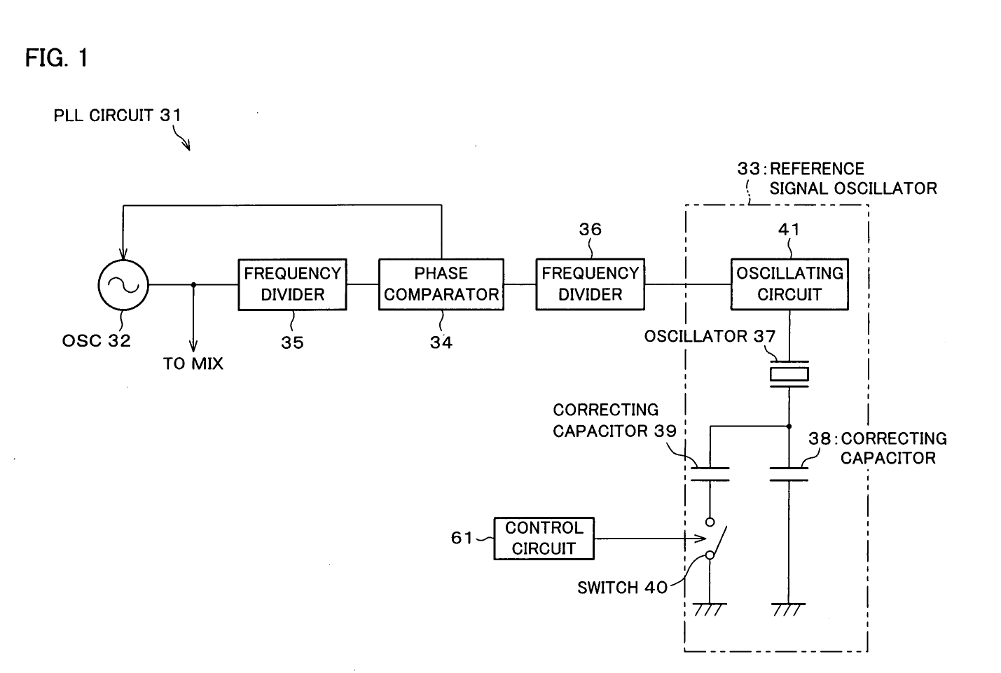

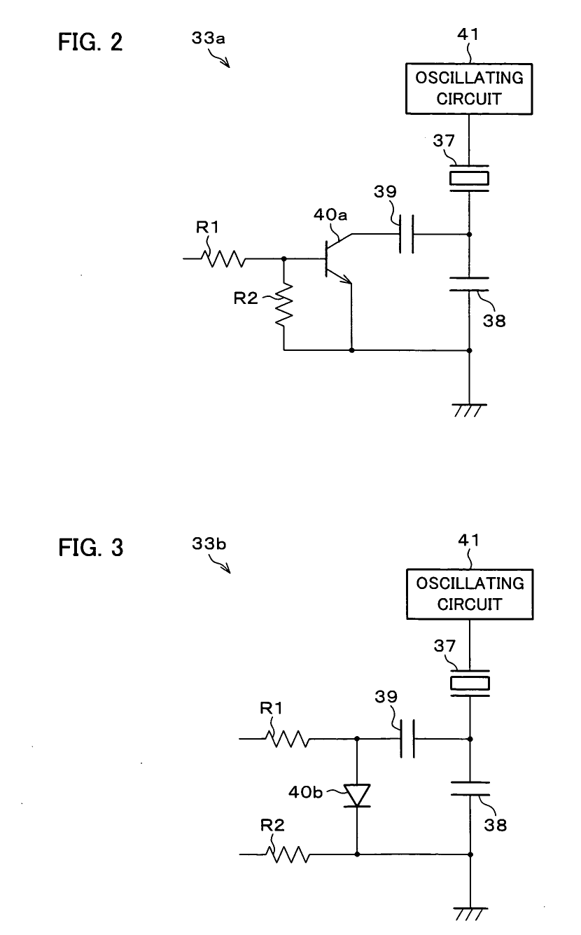

A preferred embodiment of the present invention is explained below with reference to FIG. 1, FIG. 2 and FIG. 3.

FIG. 1 is a block diagram illustrating a circuitry of a PLL circuit 31 in one embodiment of the present invention. The PLL circuit (phase locked loop) 31 includes an oscillator 32 which oscillates an LO signal, a reference signal oscillating circuit 33, a phase comparator 34, and frequency dividers 35 and 36. The oscillator 32 is realized by a voltage control oscillator which oscillates at a frequency corresponding to a DC control voltage fed by the phase comparator 34.

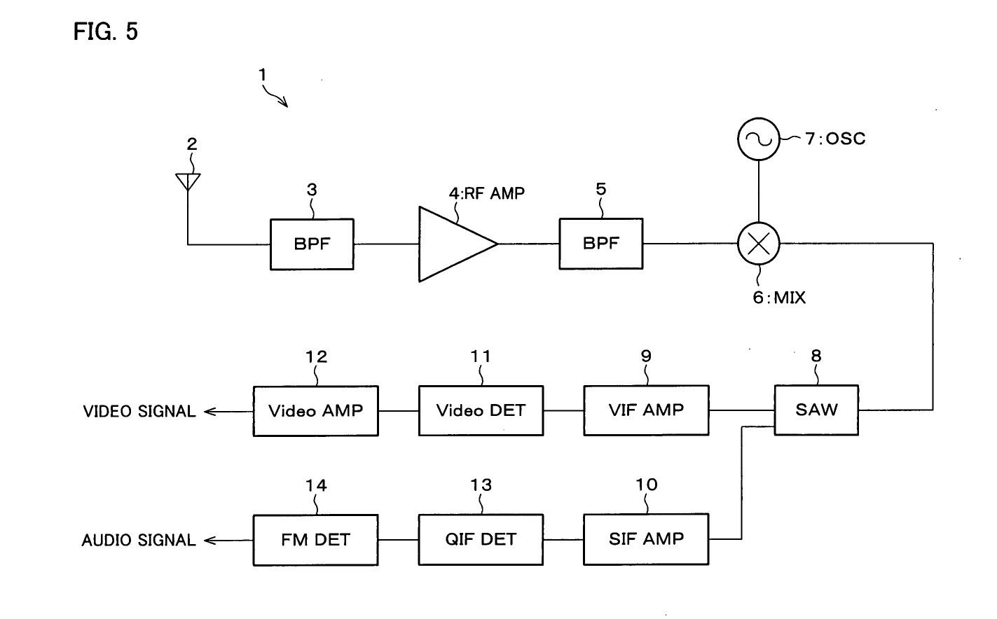

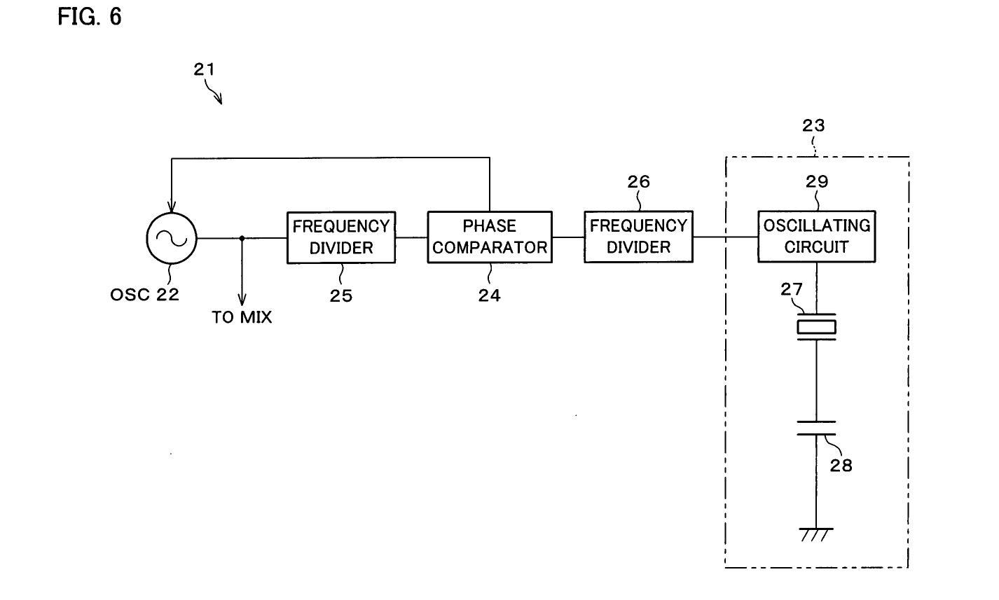

An LO signal component generated in the oscillator 32 and a reference signal component generated in the reference signal oscillating circuit 33 are divided in the frequency dividers 35, 36, respectively. Then, these divided components are compared with each other in the phase comparator 34, and feedback control is carried out in which a DC control voltage is varied to set the same phase for the divided components. The dividing ratio in the frequency divider 35 and/or the frequency divider 36 is varied by a control circuit 61, so as to convert a given RF frequency to a predetermined IF frequency in a mixing circuit 6 of a television receiver in FIG.5. Then the user can see a channel corresponding to the RF frequency. This structure is the same as the PLL circuit 21 described with reference to FIG.6.

It should be emphasized that the reference signal oscillating circuit 33 in this PLL circuit 31 includes an oscillator 37 made of a substance like crystal or ceramic, correcting capacitors 38 and 39, a switch 40, and an oscillating circuit 41. In other words, not only a series circuit of the oscillator 37 and the correcting capacitor 38 is connected to the oscillating circuit 41 as in the PLL circuit 21 of the conventional example described in FIG.6, but also the correcting capacitor 39 is provided parallel to the correcting capacitor 38. The switch 40 is closed or opened to connect or disconnect the correcting capacitor 39 to GND, so as to shift an oscillating frequency only for the reference signal of a particular channel. As a result, a beat frequency component is shifted to a frequency which is hard to recognize with human eyes. In the series circuit, either the oscillator 37 or the parallel correcting capacitors 38 and 39 may be on the GND side.

As will be described later, a control circuit 61 turns ON or OFF the switch 40 when the television receiver receives a particular channel (channel A-5 in the U.S., and channel 1 in Japan) causing interference. For other channels, the control circuit 61 turns ON the switch 40 when the switch 40 is OFF for receiving the particular channel, and turns OFF the switch 40 when the switch 40 is ON for receiving the particular channel. On the account of this, the oscillating circuit 41 shifts an oscillating frequency of the reference signal by several ten kHz from the original frequency when receiving the particular channel. When receiving channels other than the particular channel, the oscillating circuit 41 shifts the oscillating frequency back to the predetermined original frequency.

By thus shifting the frequency of the reference signal not for the entire channels but only for the particular channel, the frequency of the LO signal will not greatly shift from its specific value in a channel having a relatively high frequency. There accordingly will be no great shift of the IF signal frequency from its specific value, thus preventing deterioration of image quality.

The control circuit 61 includes a memory section and a voltage control section, for example. The memory section stores information of a channel in which interference occurs (USA: channel A-5, JPN: channel 1). The voltage control section has a D/A converter and a switching circuit, for example. For example, when a channel selected in an input tuning circuit 3 (described with reference to FIG. 5) is a channel in which interference occurs, the voltage control section varies an output voltage in order to turn ON or OFF the switch 40.

FIG. 2 and FIG. 3 are block diagrams of reference signal oscillators 33a and 33b, respectively, explaining detailed structures of the switch 40. An N-shaped transistor 40a is used for the switch 40 in the reference signal oscillator 33a shown in FIG.2. Accordingly, a control signal outputted from the control circuit 61 is divided by bias resistors R1 and R2, and is fed to the base of a transistor 40a. When the level of the control signal reaches or exceeds an ON voltage Vbe of the transistor 40a, the transistor 40a is turned ON, and the correcting capacitor 39 is connected parallel to the correcting capacitor 38.

On the other hand, a diode 40b is used for the switch 40 in the reference signal oscillator 33b shown in FIG.3. Accordingly, a control signal outputted from the control circuit 61 is fed to the anode of the diode 40b through a bias resistor R1. Similarly, another control signal outputted from the control circuit 61 is fed to the cathode of the diode 40b through a bias resistor R2. When the potential difference across the anode and cathode reaches or exceeds an ON voltage VF of the diode 40b, the diode 40b is turned ON, and the correcting capacitor 39 is connected parallel to the correcting capacitor 38.

The switch 40 can thus be structured as above. Other than the structures as exemplified above, the switch 40 can exhibit similar effects (i) when a switching element is used to selectively use the correcting capacitors 38 and 39, or (ii) when a switching element is used to short the terminals of one of the serially connected correcting capacitors 38 and 39.

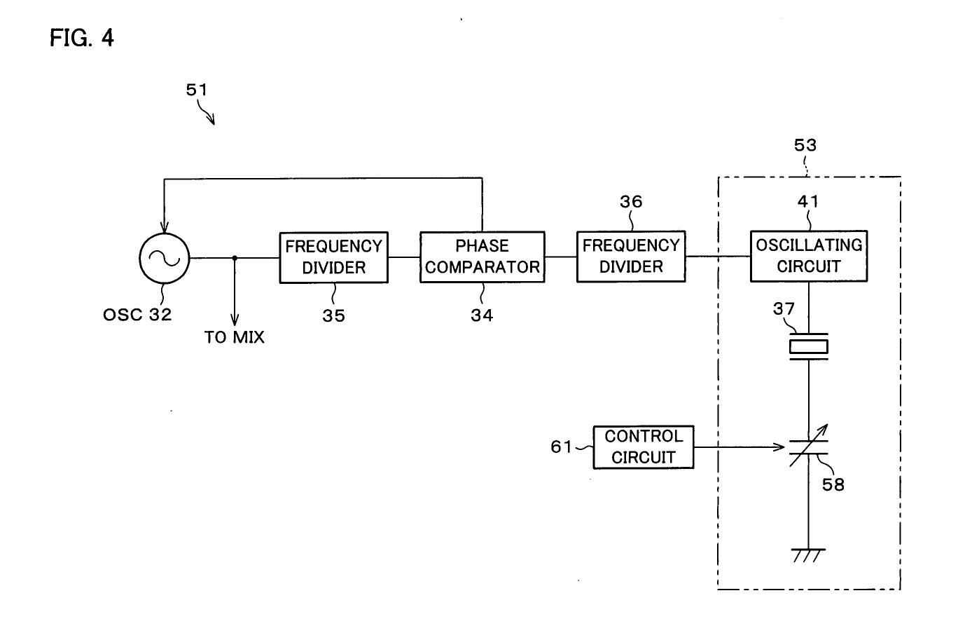

Another embodiment of the present invention is described below with reference to FIG. 4.

FIG.4 is a block diagram illustrating a circuitry of a PLL circuit 51 in another embodiment of the present invention. This PLL circuit 51 is similar to the PLL circuit 31, and accordingly corresponding members are given the same reference numerals and explanations thereof are omitted here. What is noteworthy about the PLL circuit 51 is that a correcting capacitor 58 of a reference signal oscillating circuit 53 is a variable capacitor. The control circuit 61 feeds a control voltage to the correcting capacitor 58, and varies the control voltage to vary an electrostatic capacitance. As a result, an oscillator frequency is varied.

Japanese Publication for Unexamined Patent Application No. 339652/2001 (Tokukai 2001-339652, published on Dec. 7, 2001) is available as prior art relating to the present invention. The prior art is a receiver compatible with television broadcasting and FM broadcasting, and varactor diodes are provided in an input tuning circuit, an interstage tuning circuit, and a local oscillating circuit. When the receiver receives a television signal, the same voltage is applied to all the varactor diodes, so that the difference between an LO signal frequency and a tuning frequency becomes an IF frequency for the television signal. When the receiver receives a FM signal, the voltage applied to the varactor diodes in the input synchronizing circuit and the interstage synchronizing circuit is different from the voltage applied to the varactor diodes in the local oscillating circuit, so that the difference between an LO signal frequency and a tuning frequency becomes an IF frequency for the FM signal. This allows for use of a single local oscillating circuit, instead of two as conventionally required, so as to prevent beating caused by the provision of two local oscillating circuits.

However, the object of this conventional technique is to reduce beats in a receiver compatible with television broadcasting and FM broadcasting. This differs from the present invention, whose object is to reduce beats which occur in a particular channel in a television receiver. Therefore the mechanism of beating, and the way to cope with beating are different between the present invention the prior art.

It should be noted that, instead of shifting the frequency of a reference signal for a particular channel, the dividing ratio may be shifted for a particular channel to obtain similar effects. However, this is not convenient for users unless they are the engineer (user of the unit) who is familiar with the system. Therefore, in order to enable ordinary users to more conveniently use the unit, the unit itself should be designed to deliver the effects as described in the invention. In this way, a more user friendly device can be provided.

As describe above, the PLL circuit of the present invention includes a reference signal oscillating circuit for oscillating the reference signal, wherein the reference signal oscillating circuit includes an oscillating circuit, an oscillator, and an electrostatic capacitor for oscillating. The shifting means shifts the oscillating frequency of the reference signal frequency oscillating circuit by varying an electrostatic capacitance of the electrostatic capacitor for oscillating.

According to this structure, several different methods may be used to shift the oscillating frequency of the reference signal oscillating circuit including (i) an oscillating circuit, (ii) an oscillator made from a substance such as crystal, and (iii) an electrostatic capacitor. For example, a plurality of electrostatic capacitors may be provided for oscillating, so as to allow the control means to selectively use these electrostatic capacitors with a switching element such as a transistor or a diode. Alternatively, the electrostatic capacitance of the electrostatic capacitor may be varied by serially connecting the electrostatic capacitor or in parallel. Yet another method is to use a variable capacitor as the electrostatic capacitor for oscillating, so that the electrostatic capacitance can be varied by varying the control voltage outputted from the control means. In either case, the oscillating frequency can easily be shifted in the manner described above.

Also a television receiver of the present invention uses the PLL circuit, and uses a video IF frequency of 45.75 MHz, and a video RF frequency of 91.25 MHz in a channel in which interference occurs.

According to this structure, with the television receiver whose video IF frequency is 45.75 MHz (Here, the exemplary television receiver generally conforms to the standards adopted in the United States, but it has also been adopted recently in Japan in order to achieve compatibility between the United States and Japan.), a stripe interference pattern appears on a television screen by a particular frequency relation when receiving a channel whose video RF frequency is 91.25 MHz (USA: channel A-5, JPN: channel 1). The PLL circuit according to claim 1 is used to avoid the interference pattern on a television screen.

Accordingly, a television receiver in realized which shifts the reference signal frequency only when receiving a particular channel in which interference occurs, as in channel A-5 in the US and channel 1 in Japan.

A beat reducing method for a super-heterodyne television receiver according to the present invention includes the steps of: shifting a reference signal frequency in a PLL circuit in which interference occurs; and shifting a local oscillating frequency so as to shift an interfering spurious frequency outputted from an intermediate frequency signal.

According to this structure, the beat reducing method is for a super-heterodyne television receiver in which a radio frequency (RF) signal of a selected channel is picked up as an intermediate frequency (IF) signal before it is mixed with a local oscillator signal whose frequency is controlled by the PLL circuit. In the super-heterodyne television receiver, an interfering component is added to a predetermined IF frequency when an LO frequency is mixed with a double harmonic wave of a relatively low RF frequency in a particular channel such as channel A-5 in the US and channel 1 in Japan, with the result that beats are generated and appear as a stripe pattern on a television screen. In order to solve this problem, the beat reducing method shifts the frequency of the reference signal in the PLL circuit only for a particular channel in which interference occurs. This brings about a shift in the LO signal frequency, causing the interfering spurious frequency to shift to a frequency which is almost unrecognizable. As a result, interference in the particular channel is reduced.

By thus shifting the frequency of the reference signal only for the particular channel, the frequency of the LO signal will not greatly shift from its specific value in a channel having a relatively high frequency as in UHF channel. There accordingly will be no great shift of the IF signal frequency from its specific value, thus preventing deterioration of image quality.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A PLL circuit for use in a super-heterodyne receiver, comprising:
shifting means for shifting a predetermined frequency of a reference signal; and
control means for causing the shifting means to shift the predetermined frequency of the reference signal in a channel in which interference occurs.

2. The PLL circuit as set forth in claim 1, further comprising:
a reference signal oscillating circuit for oscillating the reference signal, wherein the reference signal oscillating circuit includes an oscillating circuit, an oscillator, and an electrostatic capacitor for oscillating;
wherein the shifting means shifts an oscillating frequency of the reference signal frequency oscillating circuit by varying an electrostatic capacitance of the electrostatic capacitor for oscillating.

3. The PLL circuit as set forth in claim 2, wherein:
the electrostatic capacitor is a variable capacitor.

4. The PLL circuit as set forth in claim 1, further comprising:
a reference signal oscillating circuit for oscillating the reference signal, wherein the reference signal oscillating circuit includes (i) an oscillating circuit, (ii) an oscillator, (iii) a first electrostatic capacitor and a second electrostatic capacitor, which are for oscillating and are connected to each other in parallel, (iv) a switch for connecting and disconnecting the second electrostatic capacitor to and from the first electrostatic capacitor,
wherein:
the control means causes the switch to open or close, so as to shift the oscillating frequency of the reference signal oscillating circuit.

5. A television receiver comprising a PLL circuit for use in a super-heterodyne receiver,
wherein the PLL circuit includes (i) shifting means for shifting a predetermined frequency of a reference signal and (ii) control means for controlling the shifting means to shift the prescribed frequency of the reference signal in a channel in which interference occurs, and
wherein the television receiver uses a video IF frequency of 45.75 MHz, and a video RF frequency of 91.25 MHz in the channel in which interference occurs.

6. The television receiver as set forth in claim 5, further comprising:
a reference signal oscillating circuit for oscillating the reference signal, wherein the reference signal oscillating circuit includes an oscillating circuit, an oscillator, and an electrostatic capacitor for oscillating,
wherein the shifting means shifts the oscillating frequency of the reference signal frequency oscillating circuit by varying an electrostatic capacitance of the electrostatic capacitor for oscillating.

7. A beat reducing method for a television receiver, comprising the steps of:
shifting a reference signal frequency in a PLL circuit for a channel in which interference occurs; and
shifting a local oscillating frequency in accordance with the reference signal frequency so shifted, so as to shift an interfering spurious frequency of an intermediate frequency signal.

8. A PLL circuit for use in a super-heterodyne receiver, comprising:
a shifting circuit for shifting a predetermined frequency of a reference signal; and
a control circuit for causing the shifting circuit to shift the predetermined frequency of the reference signal in a channel in which interference occurs.

9. A PLL circuit for .use in a super-heterodyne receiver and for outputting a local oscillating signal, comprising:
a reference signal oscillating circuit for oscillating a reference signal used to determine a frequency of the local oscillating signal, wherein the reference signal oscillating circuit includes (i) an oscillating circuit, (ii) a shifting circuit for shifting a predetermined frequency of the reference signal oscillated by the oscillating circuit, (iii) a control circuit for causing the shifting circuit to shift the predetermined frequency of the reference signal in a channel in which interference occurs.
